(19) United States
(12) Patent Application Publication
(10) Pub. No.: US 2024/0339372 A1
(43) Pub. Date: Oct. 10, 2024

(54) LAMINATE CAVITY PACKAGE

(71) Applicant: Qorvo US, Inc., Greensboro, NC (US)

(72) Inventor: Carl Hinshaw, Burlington, NC (US)

(21) Appl. No.: 18/620,211

(22) Filed: Mar. 28, 2024

Related U.S. Application Data
(60) Provisional application No. 63/456,817, filed on Apr. 4, 2023.

(51) Int. Cl. H01L 23/31; H01L 23/367; H01L 23/66

(52) U.S. Cl. CPC H01L 23/315; H01L 23/3675; H01L 23/66

(57) ABSTRACT

Integrated circuit (IC) packages are disclosed. In some embodiments, a laminate is provided, having a surface and defining a cavity, wherein the cavity has an opening at the surface of the laminate. A semiconductor die is mounted in the cavity that is electrically connected to the laminate. A lid closes the opening at the surface of the laminate and an overmold is formed over the lid. This structure allows for the semiconductor die to be placed in the cavity, which is full of air, thereby improving the high frequency performance of radio frequency circuits formed in the semiconductor die.

### RELATED APPLICATIONS

This application claims the benefit of provisional patent application Ser. No. 63/456,817, filed Apr. 4, 2023, the disclosure of which is hereby incorporated herein by reference in its entirety.

### FIELD OF THE DISCLOSURE

This disclosure relates generally to integrated circuit (IC) packages and methods of manufacturing the same.

### BACKGROUND

Placing a semiconductor die in a chamber full of air is known to have various advantages. In particular, when the semiconductor die is wirebonded to traces, the frequency response of integrated circuits (ICs) that are formed in radio frequency applications is improved. When wirebonds are encased in an overmold, the semiconductor die experiences high parasitic capacitance. Unfortunately, current low cost air cavity packages that encase the semiconductor die do so in chambers that are difficult to seal and have difficulty meeting reliability requirements (MSL3).

### SUMMARY

In some embodiments, an integrated circuit (IC) package, includes: a laminate having a surface and defining a cavity, wherein the cavity has an opening at the surface of the laminate; a semiconductor die mounted in the cavity and being electrically connected to the laminate; a lid that closes the opening at the surface of the laminate; and an overmold formed over the lid. In some embodiments: the laminate includes a laminate body and a conductive structure integrated into the laminate body; the opening is formed through the laminate body and the conductive structure; and the semiconductor die is electrically connected to the conductive structure of the laminate. In some embodiments, the IC package further includes a heat sink, wherein: the heat sink is provided at a bottom of the cavity while the opening is at a top of the cavity; and the semiconductor die is mounted on the heat sink. In some embodiments, the lid is formed from Silicon or glass. In some embodiments, the surface is a top surface of the laminate and the opening is aligned with the top surface of the laminate. In some embodiments, the top surface is provided by a solder mask formed as a top layer of the laminate. In some embodiments, the laminate includes a laminate body, wherein the laminate body defines a bottom surface. In some embodiments, the bottom surface is formed by a solder mask formed from a bottom layer of the laminate. In some embodiments, the cavity is filled with air. In some embodiments, the semiconductor die is wirebonded to the laminate.

In some embodiments, a method of manufacturing an IC package includes: providing a laminate having a surface and defining a cavity, wherein the cavity has an opening at the surface of the laminate; mounting a semiconductor die in the cavity; electrically connecting the semiconductor die to the laminate; and closing the opening with a lid. The method of claims further includes forming an overmold over the lid. In some embodiments, the laminate includes a laminate body and a conductive structure integrated into the laminate body, wherein the opening is formed through the laminate body and the conductive structure, and wherein electrically connecting the semiconductor die to the laminate includes wirebonding the semiconductor die to the conductive structure of the laminate. In some embodiments, the semiconductor die is electrically connected to the conductive structure of the laminate. The method further includes an epoxy for mounting the semiconductor die in the cavity. In some embodiments, a heat sink is provided at a bottom of the cavity while the opening is at a top of the cavity and the semiconductor die is mounted on the heat sink. In some embodiments, the lid is formed from Silicon or glass. In some embodiments, the cavity is filled with air after the cavity is closed with the lid.

In some embodiments, an IC package includes: a laminate having a surface and defining a cavity, wherein the cavity has an opening at the surface of the laminate; a semiconductor die mounted in the cavity and being electrically connected to the laminate; and a lid that closes the opening at the surface of the laminate. In some embodiments: the laminate includes a laminate body and a conductive structure integrated into the laminate body; the opening is formed through the laminate body and the conductive structure; and the semiconductor die is electrically connected to the conductive structure of the laminate.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is an integrated circuit (IC) package, in accordance with some embodiments; and

FIGS. 2A-2F illustrates procedures for manufacturing the IC package shown in FIG. 1, in accordance with some embodiments.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

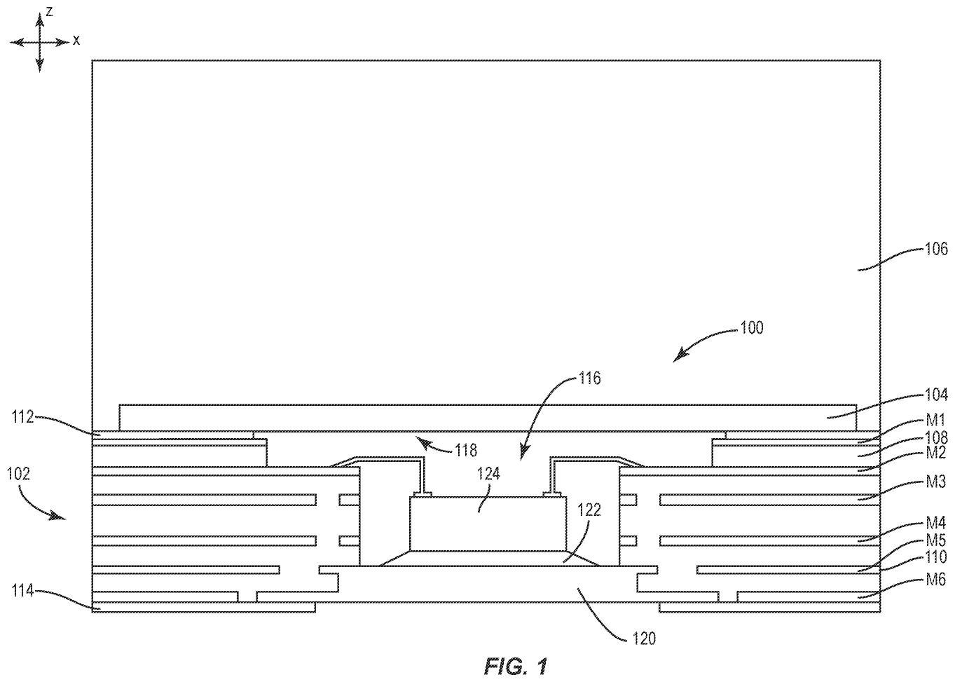

FIG. 1 is an integrated circuit (IC) package 100, in accordance with some embodiments.

The IC package 100 shown in FIG. 1 is a cross sectional view of the IC package 100, wherein layers of the IC package are stacked over in a direction relative to a z-axis. A length of the layers is defined to be parallel to an x-axis, wherein the x-axis is orthogonal to the z-axis. A width of components is defined to be parallel to a y-axis (not shown in FIG. 1).

The IC package 100 includes a laminate 102, a lid 104, and an overmold 106. The laminate 102 includes a laminate body 108 and a conductive structure 110 integrated into the laminate body 108. The laminate body 108 is formed from laminate layers. The laminate layers are formed from a laminate material such as FR1, FR2, FR3, FR4, a BT epoxy, teflon, polyimide, and/or the like. The laminate body 108 includes a solder mask 112 that provides the top layer of the laminate body 108 and a solder mask 114 that provides the bottom layer of the laminate body 108. The solder mask 112 thus provides the top surface of the laminate body 108 and the solder mask 114 provides the bottom surface of the laminate body 108.

In FIG. 1, the conductive structure 110 is formed by metallic layers (labelled M1-M6). The metallic layer M1 is formed between the solder mask 112 and the highest laminate layer. The metallic layer M6 is formed between the lowest laminate layer and the solder mask 114. The remainder of the metallic layers M2-M5 are between the laminate layers. The metallic layers M1-M6 form metallic structures used to form connections internally and externally from the laminate 102. Conductive vias (not explicitly shown) may be provided through the laminate layers in order to connect metallic features formed between different metallic layers M1-M6. In this embodiment, there are six metallic layers M1-M6 in the conductive structure 110. In other embodiments, there may be any number of metallic layers and any number of laminate layers.

A cavity 116 is formed in the laminate 102 such that the cavity 116 extends into the laminate body 108 and the conductive structure 110. The cavity 116 defines an opening 118 at an open end of the cavity 116. The opening 118 is aligned with the top surface of the laminate 102 in order to grant access into the cavity 116. The cavity 116 further defines a closed end at a bottom of the cavity 116. A heat sink 120 forms the closed end at the bottom of the cavity 116. In some embodiments, the heat sink 120 is a plated heat sink. An epoxy 122 is provided on a top surface of the heat sink 120 that is within the cavity 116. A semiconductor die 124 is attached to the heat sink 120 and, thereby, is mounted in the cavity 116. The lid 104 is then placed onto the top surface of the laminate 102 to close the cavity 116. In some embodiments, the lid 104 is made of Silicon or glass. A die attach film (DAF) (e.g., NEX-130XT) is applied to the Silicon or glass lid 104 to attach the lid 104 to the laminate. The cavity 116 is filled with air. The overmold 106 is formed over and on top of the lid 104 and the solder mask 112.

The semiconductor die 124 is electrically connected to the conductive structure 110 of the laminate 102. In this manner, electrical signals can be input and output from the semiconductor die 124. In FIG. 1, the semiconductor die 124 is wirebonded to metallic layer M2 of the conductive structure 110. By encapsulating the semiconductor die 124, the performance of the IC circuits in the semiconductor die 124 is improved, particularly where the IC circuits are used for high frequency applications. Furthermore, the semiconductor die 124 has improved parasitic capacitance since the cavity 116 is filled with air rather than being encapsulated in overmold 106. Furthermore, rather than having to plug a hole in a lid (which is a common practice in cavity package assembly), the semiconductor die 124 is better protected in the IC package 100 while the IC package 100 maintains a low profile. In some embodiments, creating the cavity 116 in the laminate 102 is a fast, inexpensive, and repeatable approach.

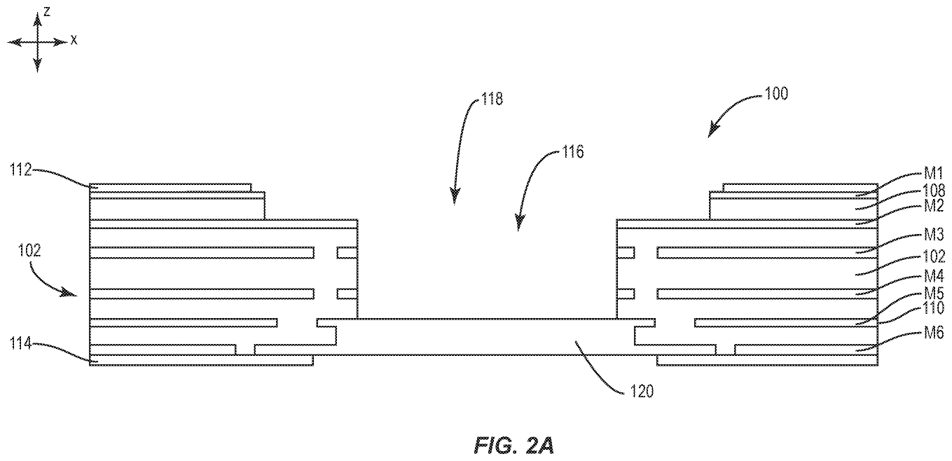

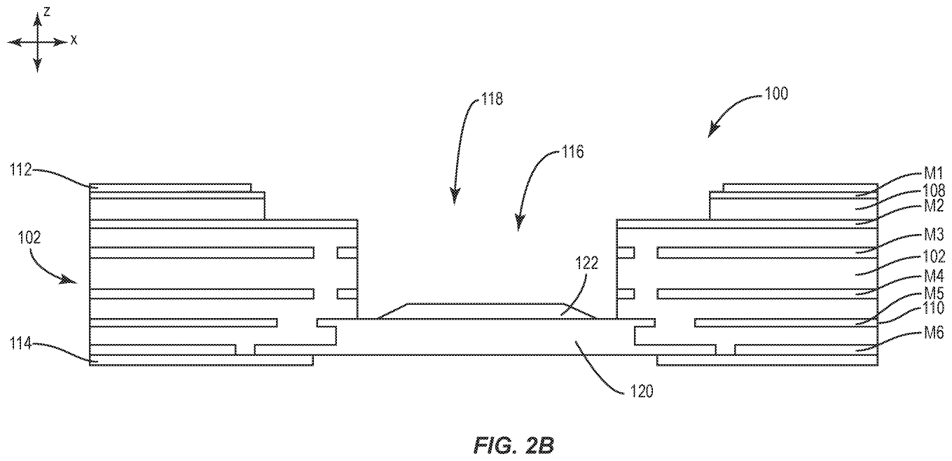

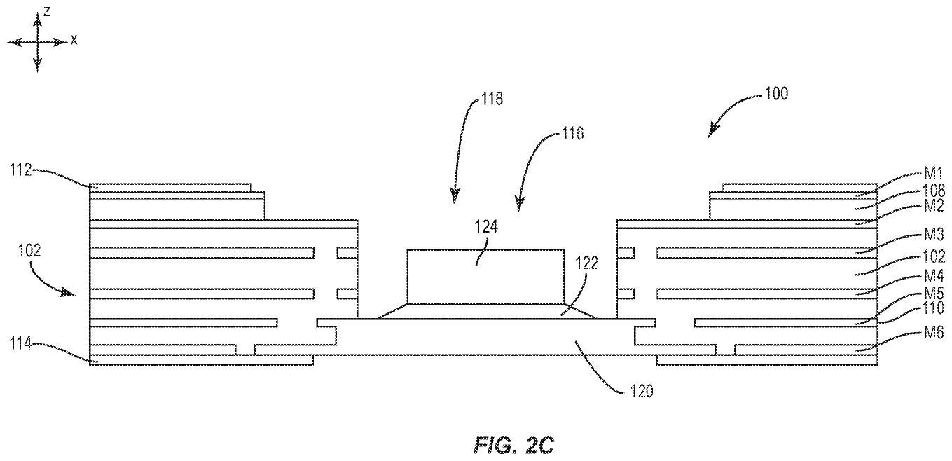

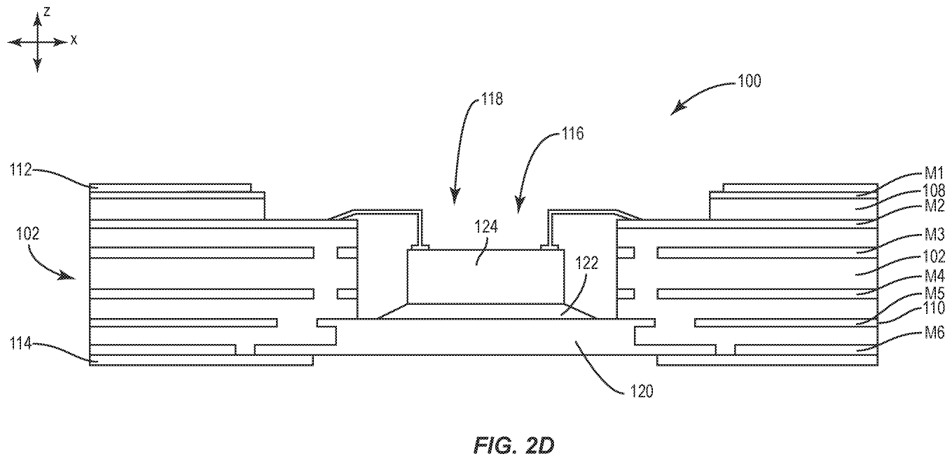

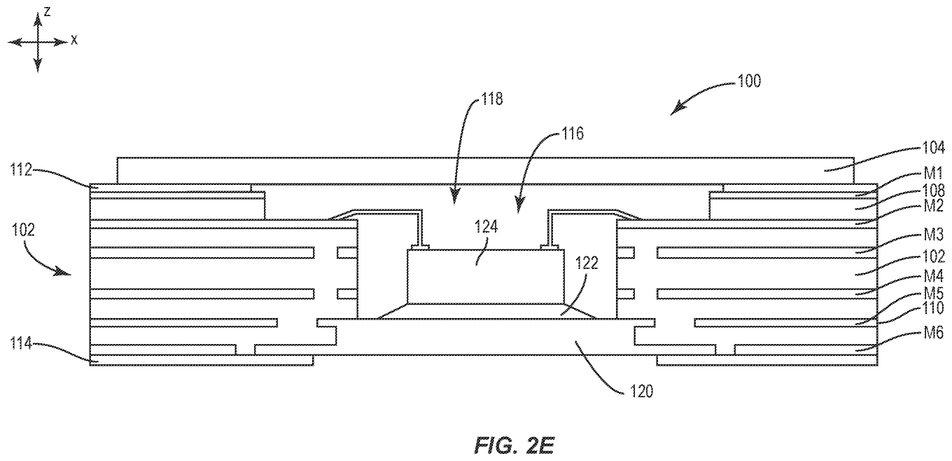

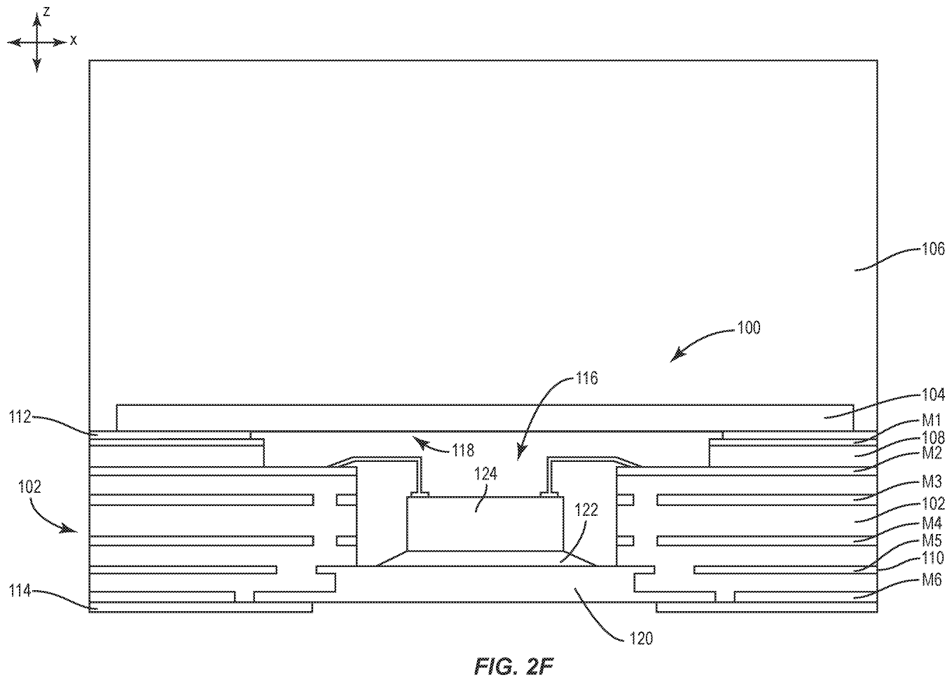

FIGS. 2A-2F illustrate procedures for manufacturing the IC package 100 shown in FIG. 1, in accordance with some embodiments.

In FIG. 2A, the laminate 102 is provided. The laminate 102 has the laminate body 108. The conductive structure 110 is integrated into the laminate body 108. The opening 118 is formed through the laminate body 108 and the conductive structure 110. An example of the laminate 102 is an Access PHS 6 layer laminate, in accordance with some embodiments.

The laminate 102 defines the cavity 116. The cavity 116 has the opening 118 at the surface of the solder mask 112 of the laminate 102. The heat sink 120 is provided at the bottom of the cavity 116.

In FIG. 2B, the epoxy 122 is provided on the top surface of the heat sink 120. An example of the epoxy 122 is Atrox D800HT5, in accordance with some embodiments.

In FIG. 2C, the semiconductor die 124 is mounted on the epoxy 122, thereby mounting the semiconductor die 124 in the cavity 116. In some embodiments, prior to the procedure shown in FIG. 2C, the semiconductor die 124 is grinded to a specific thickness (TBD). A DAF (e.g., NEX-130XT) is applied to the top surface of the laminate 102.

In FIG. 2D, the semiconductor die 124 is electrically connected to the laminate 102. In this embodiment, the semiconductor die 124 is wirebonded to the conductive structure 110 at the metallic layer M2.

In FIG. 2E, the opening 118 of the cavity 116 is closed with the lid 104. In some embodiments, the lid 104 is formed from Silicon. In other embodiments, the lid 104 is formed from glass. In some embodiments, the surface of the solder mask 112 is the attachment surface for the lid 104. The silicon or glass lid 104 is singulated to the appropriate size and then picked up and placed on the laminate solder mask 112, where the silicon or glass lid 104, with the applied DAF, covers the opening 118 of the laminate 102.

In FIG. 2F, the overmold 106 is formed over the lid 104. An example of the overmold 106 is Sumitomo G750LRE, in accordance with some embodiments.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. An integrated circuit (IC) package, comprising:
a laminate having a surface and defining a cavity, wherein the cavity has an opening at the surface of the laminate;
a semiconductor die mounted in the cavity and being electrically connected to the laminate;
a lid that closes the opening at the surface of the laminate; and
an overmold formed over the lid.

2. The IC package of claim 1, wherein:
the laminate comprises a laminate body and a conductive structure integrated into the laminate body;
the opening is formed through the laminate body and the conductive structure; and
the semiconductor die is electrically connected to the conductive structure of the laminate.

3. The IC package of claim 1, further comprising a heat sink, wherein:
the heat sink is provided at a bottom of the cavity while the opening is at a top of the cavity; and
the semiconductor die is mounted on the heat sink.

4. The IC package of claim 1, wherein the lid is formed from Silicon or glass.

5. The IC package of claim 1, wherein the surface is a top surface of the laminate and the opening is aligned with the top surface of the laminate.

6. The IC package of claim 5, wherein the top surface is provided by a solder mask formed as a top layer of the laminate.

7. The IC package of claim 1, wherein the laminate comprises a laminate body, wherein the laminate body defines a bottom surface.

8. The IC package of claim 7, wherein the bottom surface is formed by a solder mask formed from a bottom layer of the laminate.

9. The IC package of claim 1, wherein the cavity is filled with air.

10. The IC package of claim 1, wherein the semiconductor die is wirebonded to the laminate.

11. A method of manufacturing an integrated circuit (IC) package, comprising:
providing a laminate having a surface and defining a cavity, wherein the cavity has an opening at the surface of the laminate;
mounting a semiconductor die in the cavity;
electrically connecting the semiconductor die to the laminate; and
closing the opening with a lid.

12. The method of claim 11, further comprising forming an overmold over the lid.

13. The method of claim 11, wherein the laminate comprises a laminate body and a conductive structure integrated into the laminate body, wherein the opening is formed through the laminate body and the conductive structure and wherein electrically connecting the semiconductor die to the laminate comprises wirebonding the semiconductor die to the conductive structure of the laminate.

14. The method of claim 13, wherein:
the semiconductor die is electrically connected to the conductive structure of the laminate.

15. The method of claim 11, further comprising an epoxy for mounting the semiconductor die in the cavity.

16. The method of claim 11, wherein:
a heat sink is provided at a bottom of the cavity while the opening is at a top of the cavity; and
the semiconductor die is mounted on the heat sink.

17. The method of claim 11, wherein the lid is formed from Silicon or glass.

18. The method of claim 11, wherein the cavity is filled with air after the cavity is closed with the lid.

19. An integrated circuit (IC) package, comprising:
a laminate having a surface and defining a cavity, wherein the cavity has an opening at the surface of the laminate;
a semiconductor die mounted in the cavity and being electrically connected to the laminate; and
a lid that closes the opening at the surface of the laminate.

20. The IC package of claim 19, wherein:
the laminate comprises a laminate body and a conductive structure integrated into the laminate body;
the opening is formed through the laminate body and the conductive structure; and
the semiconductor die is electrically connected to the conductive structure of the laminate.
